(19) United States
(12) Patent Application Publication
(10) Pub. No.: US 2008/0310119 A1
(43) Pub. Date: Dec. 18, 2008

(54) Clip on heat sink

(75) Inventor: Lawrence M. Giacoma, Plano, TX (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Tellabs Bedford, Inc., Naperville, IL (US)

(21) Appl. No.: 11/818,160

(22) Filed: Jun. 13, 2007

(51) Int. Cl. H05K 7/20

(52) U.S. Cl. 361/719; 361/710

(57) ABSTRACT

A heat sink according to an embodiment of the present invention can be attached to any device without printed circuit board (PCB) modification. The heat sink may clamp on device edges, which does not stress solder balls between the device and heat sink. The heat sink may be configured to be installed to or removed from the device without special tools. The heat sink may be extruded, machined, or die cast aluminum or other material to reduce part and tooling cost, and may be black anodized to be electrically non-conductive. A single-piece embodiment eliminates a need for a separate clip, thereby increasing heat transfer by as much as twenty-five percent or more over heat sinks employing clips. Further, wavy fins or other heat dissipation configurations may increase heat transfer by at least eleven percent, for a total heat transfer improvement of at least thirty-six percent over a two-part heat sink.

### BACKGROUND OF THE INVENTION

As integrated circuit and similar technologies have improved, greater functionality has been incorporated into devices. Along with this expanded functionality, the size of devices has diminished, resulting in higher clocking frequencies and increased power dissipation per square area. As a consequence, today's integrated circuit devices generate more heat while possessing smaller surface areas to dissipate the heat. Therefore, it is useful to have a high rate of heat transfer from the integrated circuit package to maintain the temperature of the integrated circuit within safe operating limits. Excessive heat may adversely affect the performance of the circuit, cause permanent degradation of its components, and increase failure rates.

A heat exchange with a heat sink may be used for transferring heat away from a heat source, such as an electronic component or printed circuit board (PCB), to maintain the component within an optimum operating temperature range, so that the component can operate continuously and with maximized efficiency.

Conventional heat sinks typically contain a plurality of fins or rods that extend from a base that contacts the heat generating integrated circuit. Some heat sinks employ securing mechanisms that enlarge or exceed the heat sink envelope. This increases the footprint of the electronic component/heat sink assembly, thereby reducing the surface area of the PCB available for mounting elements and potentially imposing a limit on the height of nearby elements on the PCB.

### SUMMARY OF THE INVENTION

One embodiment of a heat sink, and corresponding method for removably securing the heat sink, comprises a contact plate with a conduction side and a convection side. The conduction side is configured to be in thermal communication with a heat generating device. Extending outward from the convection side of the contact plate are a plurality of thermally conductive elements. The example heat sink includes spring clips with an elasticity to enable bending outward from the contact plate. The spring clips, due to their elasticity, self-restore inward toward the contact plate to self-couple the heat sink with the heat generating device.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1A is an isometric diagram of a heat sink in an example embodiment of the present invention.

FIG. 1B is an isometric diagram of the heat sink of FIG. 1A in application with a heat generating device having a ball grid array (BGA) used to solder to a printed circuit board (PCB).

FIG. 2A is an isometric diagram of a heat sink with spring clips with tabs coupled to a heat generating device in an example embodiment of the present invention.

FIG. 2B is an isometric diagram of a heat sink having a contact plate and spring clips with slots at a bend between extending outward from and returning toward the contact plate to provide openings for a tool (not shown) to bend the spring clips laterally away from the contact plate.

FIG. 2C is an isometric diagram illustrating stress exerted on the spring clips in an unrelaxed state.

FIG. 3 is an isometric diagram of a heat sink with spring clips defining a central portion of the spring clips and legs separated by the central portion in an example embodiment of the present invention

FIGS. 4A-4C are force diagrams of a combination of the spring clips and the contact plate in example embodiments of the present invention annotated with forces exerted by the spring clip on a heat generating device.

### DETAILED DESCRIPTION OF THE INVENTION

A description of example embodiments of the invention follows.

Conventional heat sinks and clips for their attachment are inefficient, expensive to produce and bulky. Conventional heat sinks typically include both a body and a fastener. That fastener may be a curved piece that applies pressure on an electronic component to which the heat sink is applied when installed. However, such fasteners reduce the available convection surface area of heat sinks, thereby reducing their efficiency. Other conventional heat sinks employ spring action for securing the body to the electronic component, but require special modification of the PCB. Further conventional heat sinks require screws, push pins, clips, anchors, or other forms of mechanical attachment that are additional parts beyond the body, itself, that take up valuable surface area on the PCB and block air flow to the convection surfaces of the heat.

Further, conventional methods of securing a heat sink to an integrated circuit or other heat generating device can weaken ball grid array (BGA) solder connections between the integrated circuit and the PCB through application of stresses. In a BGA, balls of solder are stuck to the bottom of the package, here the integrated circuit package, which is placed on a PCB that carries copper pads in a pattern corresponding to the solder ball pattern. The assembly is then heated, either in a reflow oven or by an infrared heater, causing the solder balls to melt. Surface tension causes the molten solder to hold the package in alignment with the circuit board, at the correct separation distance, while the solder cools and solidifies. Conventional clip-on heat sinks apply a bending moment to the heat generating device, which stresses the solder balls-to-PCB connections and decreases component reliability or useful life. Without a heat sink, the outer balls will generally fail over time due to heating and inherent stresses. By adding more stress through an application of a heat sink, failures will occur even quicker and more often.

According to an example embodiment of the present invention, a heat sink, and corresponding method for removably securing the heat sink, comprises a contact plate with a conduction side and a convection side. The conduction side is configured to be in thermal communication with a heat generating device. Extending outward from the convection side of the contact plate are a plurality of thermally conductive elements. The example heat sink includes spring clips with an elasticity to enable bending outward from the contact plate. The spring clips, due to their elasticity, self-restore inward toward the contact plate, via a restorative force, to self-couple the heat sink with the heat generating device.

The spring clips may be configured to bend substantially laterally outward from the contact plate. Further, the spring clips may extend outward from the convection side of the contact plate, and may so extend at respective edges of the contact plate and return toward and below the respective edges of the contact plate.

The spring clips may include tabs extending, at least, partially under the heat generating device. The tabs may apply a securing force to the underside of the heat generating device to minimize or prevent vertical movement of the heat sink on the heat generating device. The tabs may be angled relative to or substantially parallel to the conduction side of the contact plate.

The spring clips may include a central portion and legs separated by the central portion by respective slits. The legs may apply a securing force to an edge of the heat generating device to minimize or prevent horizontal movement of the heat sink on the heat generating device. The central portion may be configured to contact the heat generating device in a clamped state. The legs may be configured to be in an unclamped state while the central portion is in the clamped state.

A combination of the spring clips and the contact plate may exert forces on the heat generating device in a manner that does not affect a mechanical arrangement between the heat generating device and a member to which the heat generating device is coupled, such as a PCB. At least some of the forces exerted by the combination of the spring clips and the contact plate may be exerted laterally inward, diagonally upward, or vertically upward on the heat generating device.

The thermally conductive elements may provide more convection surface area than plate elements with flat surfaces, and may be configured to increase airflow across them.

The spring clips may also define slots to provide openings for a tool to bend the clips at a bend between the portion of the spring clips that extends outward and that portion that returns toward and below the contact plate.

The heat sink may be attached to the device without PCB modification. The heat sink may be extruded, machined, or die cast aluminum or other material to reduce part and tooling cost, and may be black anodized to be electrically non-conductive. A single-piece embodiment eliminates a need for a separate clip, thereby increasing heat transfer by as much as twenty-five percent or more over heat sinks employing clips. Further, wavy fins or other heat dissipation configurations may increase heat transfer by at least eleven percent, for a total heat transfer improvement of at least thirty-six percent over a two-part heat sink.

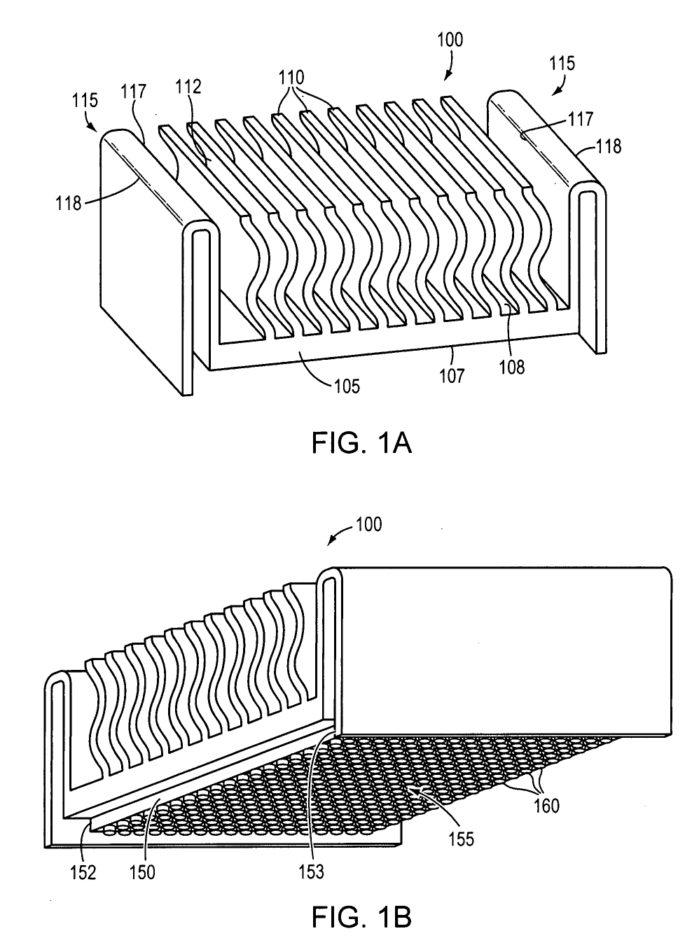

FIG. 1A is an isometric diagram of a heat sink 100 according to an example embodiment of the present invention. The heat sink 100 includes a contact plate 105, having a conduction side 107 and a convection side 108. The conduction side 107 is configured to be in thermal communication with a heat generating device (not shown), such as an integrated circuit or a variety of other optical, electrical, or mechanical components. The heat sink 100 further includes a plurality of thermally conductive elements 110 extending outward from the convection side 108 of the contact plate 105. In this example embodiment, the thermally conductive elements 110 are wavy fins to provide more convection surface area 112 than if they were plate elements with flat surfaces (not shown) as understood in the art. Further, the thermally conductive elements 110 may be configured to increase airflow across them by defining narrowing airflow paths in a direction of airflow across them or being airfoil shaped, thereby increasing the efficiency of the heat sink 100. Here, the thermally conductive elements 110 are aligned in a parallel manner such that air flows freely through the channels created by opposing thermally conductive elements 110.

The heat sink 100 further includes spring clips 115 that extend outward, here upward, from the convection side 108 of the contact plate 105 at respective edges in this embodiment, and return toward and below the contact plate 105. In other embodiments, the spring clips 115 may connect to the contact plate 105 inside of edges of the contact plate 105. In this example embodiment, the spring clips 115 extend outward for a length approximately equal to the length of the thermally conductive elements 110, bend outward away from the thermally conductive elements 110 at a first bend 117, continue for a distance substantially parallel to the contact plate 105 or have a small radius, and bend back toward the contact plate 105 at a second bend 118. Although the spring clips 115 are illustrated as approximately the same height as the thermally conductive elements 110, this is not a requirement; the spring clips 115 may be taller, shorter, or substantially the same height as the thermally conductive elements 110. The spring clips 115 then continue below the contact plate 105 such that they may make contact with the heat generating device. Further, in this example embodiment, the spring clips 115 have an elasticity such that they may be bent outward from the contact plate 105 and self-restore laterally inward toward the contact plate 105 to self-couple with the heat generating device.

FIG. 1B is an isometric diagram of the heat sink 100 of FIG. 1A in application with a heat generating device 150 secured via a ball grid array (BGA) 155 to a printed circuit board (PCB) (not shown). The heat sink 100 increases the reliability of the heat generating device 150 by not exerting stresses non-uniformly upward, or downward, or a combination thereof, on the solder balls 160 of the BGA 155. As illustrated, the spring clips 115 press laterally inward onto respective edges 152, 153 of the heat generating device 150. In this example embodiment, the heat sink 100 can be secured to and removed from the heat generating device 150 without use of special tools and uses substantially no additional PCB surface area beyond the heat-generating device 150.

The heat sink 100 may be black anodized so that its surface is non-electrically conductive. The heat sink 100 may be fabricated through an extrusion process, machining process, or die casting process, for example, and is inexpensive to fabricate, in part, because it is a single piece. Moreover, because the heat sink 100 uses substantially little PCB surface area beyond the heat generating device, use of the heat sink 100 may not require modification to the PCB or any other member to which the heat generating device 150 is secured.

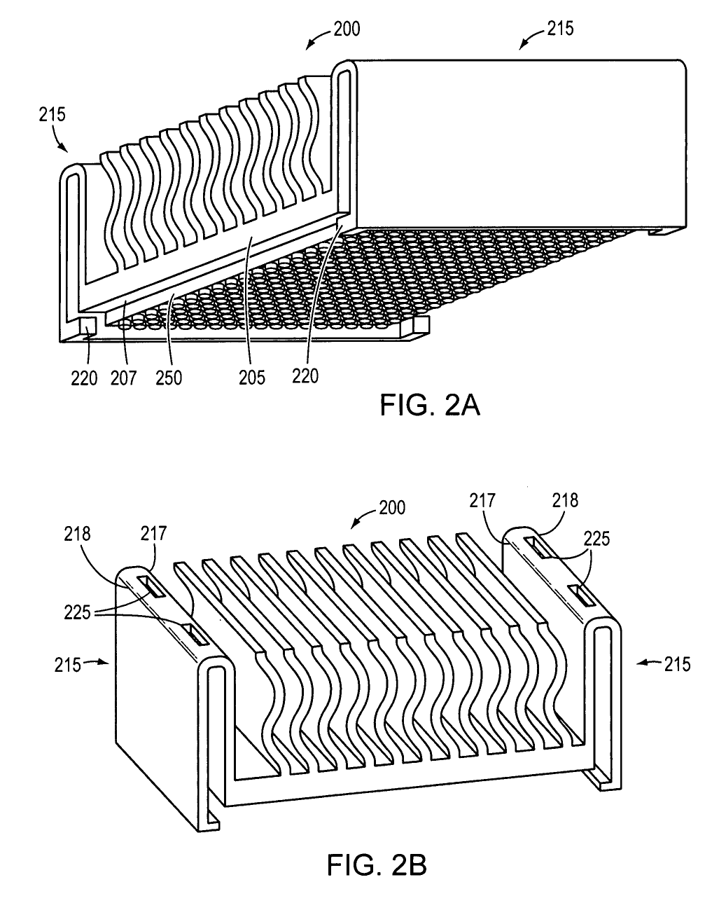

FIG. 2A is an isometric diagram of a heat sink 200 according to an embodiment with spring clips 215 further comprising tabs 220 that can be used to affix the heat sink 200 to a heat generating device 250. In an example embodiment of the present invention, the tabs 220 may extend at least partially under the heat generating device 250 to prevent the heat sink 200 from falling off the heat generating device, such as in applications that may experience mechanical vibrations or shocks. These tabs 220 may be substantially parallel to the conduction side 207 of the contact plate 205 or may be angled relative to the conduction side 207 of the contact plate 205.

Moreover, as illustrated in FIG. 2B, the spring clips 215 may define one or more slots 225 at a bend 217, 218 between extending outward from and returning toward the contact plate 205 to provide openings for a tool (not shown) to bend the spring clips 215. This tool does not have to be a custom tool specific to the heat sink 200; for example, the tool may be a flat-head screwdriver. Bending the spring clips 215 via the tool counteracts the elastic spring forces exerted by the spring clips 215, allowing the heat sink 200 to be seated on a heat generating device (not shown). Relaxing of the tool thereby applies the elastic forces exerted by the spring clips 215 against the heat generating device as they return to their relaxed position. The heat sink 200 may be removed from the heat generating device by similarly applying the tool and bending the spring clips 215, thereby decoupling the spring clips 215 from the heat generating device.

FIG. 2C is an isometric diagram illustrating stresses exerted at locations A-F on the spring clips 215 when the spring clips are in an unrelaxed state when bent by the tool.

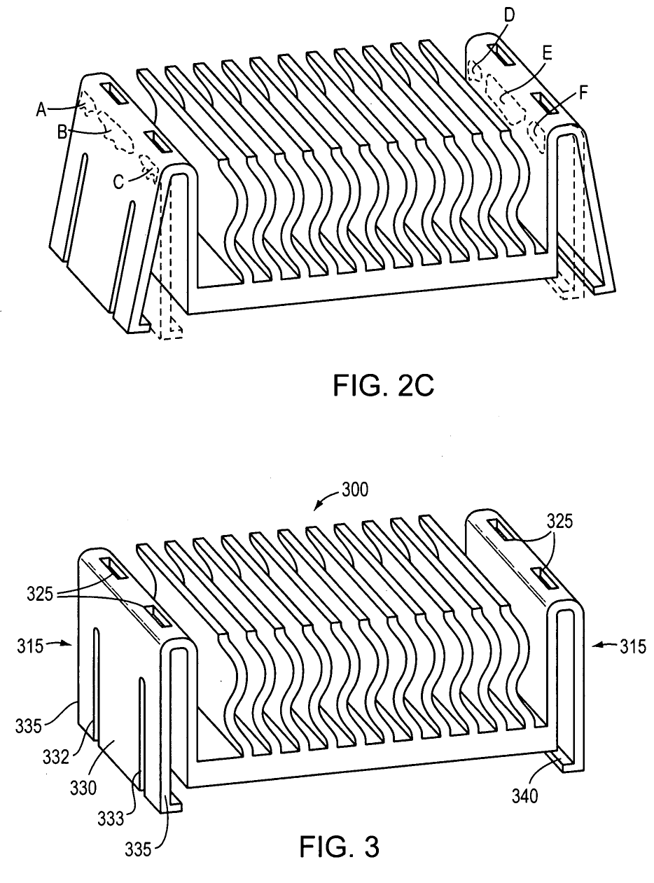

FIG. 3 is an isometric diagram of a heat sink 300 with spring clips 315 defined by a central portion 330 and legs 335, separated by the central portion 330 coupled to a heat generating device 350 in an example embodiment of the present invention. Between the central portion 330 and each respective leg 335 is a slit 332, 333. The legs 335 extend beyond the surface of the heat generating device such that they prevent lateral movement of the heat sink 300 on the heat generating device, and tabs 340 on at least the central portion 220 are configured to be positioned under the heat generating device to prevent vertical movement, thus making the heat sink able to withstand harsh mechanical environments. In this embodiment, the central portion 330 is configured to contact the heat generating device in a clamped state, and the legs 335 may be in an unclamped state while the central portion 330 is in the clamped state. The heat sink 300 may then be removed using one or more slots 325 in a similar manner as discussed above with reference to FIG. 2.

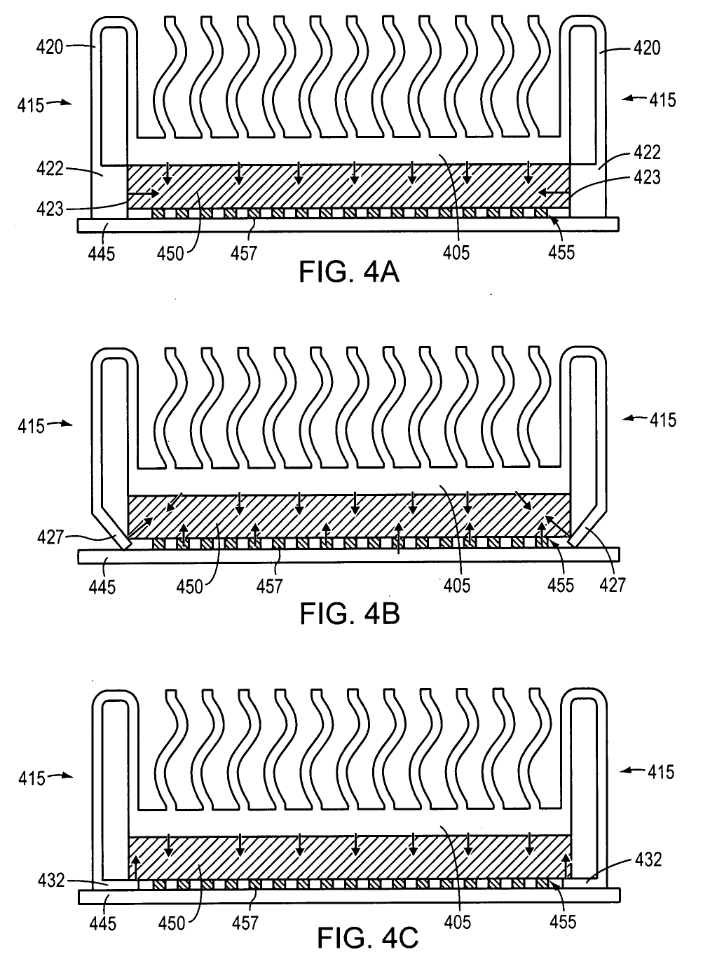

FIGS. 4A-4C are force diagrams illustrating the forces exerted by a combination of the spring clips 415 and the contact plate 405 on a heat generating device 450. In this example embodiment, the heat generating device 450 is an integrated circuit secured to a PCB 445 via a BGA 455. In example embodiments of the present invention, the forces may be exerted in a manner that does not affect a mechanical arrangement between the heat generating device 450 and a member 445 to which the heat generating device 450 is coupled. To achieve this result, the spring clips 415 may exert forces laterally inward on the heat generating device 450, as illustrated in FIG. 4A, via the spring portions 420 of the spring clips 415 at contact structures 422 with walls 423 substantially perpendicular to the contact plate 405. Further, as illustrated in FIG. 4B, a similar result may be achieved through use of angled spring portions 427 of the spring clips 415 such that the spring clips 415 exert forces diagonally upward on the heat generating device 450. Moreover, a similar result may be achieved through use of spring portions 432 of the spring clips 415 such that the spring clips 415 exert forces vertically upward on the heat generating device 450, as illustrated in FIG. 4C. In these example embodiments, the combination of the spring clips 415 and the contact plate 405 exerts forces, if at all, substantially uniformly across all solder joints 457 of the BGA 455. Each arrow indicating a force is only intended to indicate the direction component of the force vector and not the magnitude relative to the other arrows.

While this invention has been particularly shown and described with references to example embodiments thereof, it will be understood by those skilled in the art that various changes in form and details may be made therein without departing from the scope of the invention encompassed by the appended claims.

For example, any material or combination of materials that can be used as heat sink material(s) may be employed to compose heat sinks described by way of example herein. Although the contact plate and fins are generally illustrated herein as being square or rectangular, it should be understood that any shape may be employed. Moreover, although the contact plates are illustrated as being substantially flat, it should be understood that any profile may be employed to support application to non-flat surfaces. In addition, coupling springs (not shown) that may be wavy and used to apply a force directed upward toward the contact plate and downward toward the heat generating device may be used to apply a balanced distribution of force and thermal coupling across the heat generating device while being held to the heat generating device by the tabs or other elements used to hold the heat sink in place.

In other example embodiments, the heat sink can be composed of multiple detachable subcomponents for selectable configurations. For example, flat fins may be detached and replaced by wavy or curved fins for various applications. The fins may be inserted into slots (not shown) on or in the contact plate. The spring clips may also be detachable and replaced with spring clips of higher or lower restorative forces to secure the heat sink to the heat generating device with selectable levels of force, with selectable directions of force, and selectable parameters related to physical or other properties associated with the spring clips.

What is claimed is:

1. A heat sink comprising:
a contact plate with a conduction side and a convection side, the conduction side configured to be in thermal communication with a heat generating device;
a plurality of thermally conductive elements extending outward from the convection side of the contact plate;
spring clips extending outward from the contact plate and returning toward and below the contact plate, the spring clips having elasticity to enable bending outward from the contact plate and self-restoring inward toward the contact plate to self-couple with the heat generating device.

2. The heat sink of claim 1 wherein the spring clips are configured to bend substantially laterally outward from the contact plate.

3. The heat sink of claim 1 wherein the spring clips extend outward from the convection side of the contact plate.

4. The heat sink of claim 3 wherein the spring clips extend outward from the convection side of the contact plate at respective edges of the contact plate and return toward and below the respective edges of the contact plate.

5. The heat sink of claim 1 wherein the spring clips further include tabs at least partially extending under the heat generating device.

6. The heat sink of claim 5 wherein the tabs are angled relative to the conduction side of the contact plate.

7. The heat sink of claim 5 wherein the tabs are substantially parallel to the conduction side of the contact plate.

8. The heat sink of claim 1 wherein the spring clips further include:
a central portion; and
legs separated by the central portion by respective slits, the central portion configured to contact the heat generating device in a clamped state and the legs configured to be in an unclamped state while the central portion is in the clamped state.

9. The heat sink of claim 1 wherein a combination of the spring clips and the contact plate exerts forces on the heat generating device in a manner that does not affect a mechanical arrangement between the heat generating device and a member to which the heat generating device is coupled.

10. The heat sink of claim 9 wherein the spring clips exert at least some forces laterally inward on the heat generating device.

11. The heat sink of claim 9 wherein the spring clips exert at least some forces diagonally upward on the heat generating device.

12. The heat sink of claim 9 wherein the spring clips exert forces vertically upward and downward on the heat generating device.

13. The heat sink of claim 1 wherein the thermally conductive elements provide more convection surface area than if plate elements with flat surfaces.

14. The heat sink of claim 1 wherein the thermally conductive elements are configured to increase airflow across them.

15. The heat sink of claim 1 wherein the spring clips define slots to provide openings for a tool to bend the clips at a bend between extending outward and returning toward and below the contact plate.

16. A method of removably securing a heat sink comprising:
applying a restorative force to self-couple a heat sink to a heat generating device.

17. The method of claim 16 further comprising:
countering the restorative force to remove the heat sink from the heat generating device.

18. The method of claim 16 wherein applying the restorative force includes applying the restorative force from a convection side of the heat sink.

19. The method of claim 18 wherein applying the restorative force includes applying the restorative force from the edges of the convection side of heat sink.

20. The method of claim 16 wherein applying the restorative force includes applying a securing force to the underside of the heat generating device to minimize or prevent vertical movement of the heat sink on the heat generating device.

21. The method of claim 20 wherein applying the securing force includes applying the securing force at an angle relative to the underside of the heat generating device.

22. The method of claim 20 wherein applying the securing force includes applying the securing force substantially perpendicular to the underside of the heat generating device.

23. The method of claim 16 wherein applying the restorative force includes applying a securing force to an edge of the heat generating device to minimize or prevent horizontal movement of the heat sink on the heat generating device.

24. The method of claim 16 wherein applying the restorative force to the heat generating device is performed in a manner that does not affect a mechanical arrangement between the heat generating device and a member to which the heat generating device is coupled.

25. The method of claim 24 wherein applying the restorative force includes applying at least some restorative force laterally inward on the heat generating device.

26. The method of claim 24 wherein applying the restorative force includes applying at least some restorative force diagonally upward on the heat generating device.

27. The method of claim 24 wherein applying the restorative force includes applying restorative forces vertically upward and downward on the heat generating device.

28. The method of claim 17 wherein applying the restorative force includes resisting bending forces produced by a tool acting upon the heat sink to counter the restorative force.

29. A heat sink comprising:
means for dissipating heat from a heat generating device; and
means for self-coupling the heat dissipating means to the heat generating device.
